(19) United States
(12) Patent Application Publication
(10) Pub. No.: US 2009/0026524 A1
(43) Pub. Date: Jan. 29, 2009

(54) Stacked Circuits

(76) Inventors: Franz Kreupl, Muenchen (DE); Josef Willer, Riemerling (DE); Doris Keitel-Schulz, Hoehenkirchen (DE)

Correspondence Address: SLATER & MATSIL, L.L.P., 17950 PRESTON ROAD, SUITE 1000, DALLAS, TX, 75252, US

(21) Appl. No.: 11/829,700

(22) Filed: Jul. 27, 2007

(51) Int. Cl. H01L 29/788; H01L 21/30; H01L 23/48

(52) U.S. Cl. 257/316; 257/777; 438/459; 257/E29.3; 257/E21.211

(57) ABSTRACT

An integrated circuit includes a first integrated circuit layer including at least one first transistor channel region and having a wafer bonding interface. The integrated circuit may further include at least one second integrated circuit layer including at least one second transistor channel region and being arranged at the wafer bonding interface of the first integrated circuit layer.

### TECHNICAL FIELD

This description is directed to multi-layer integrated circuits and stacked circuits.

### BRIEF DESCRIPTION OF THE DRAWINGS

Details of one or more implementations are set forth in the accompanying exemplary drawings and exemplary description below. Other features will be apparent from the description and drawings, and from the claims.

FIG. 1 shows an exemplary multi-layer integrated circuit;

FIG. 2 shows another exemplary multi-layer integrated circuit;

FIG. 3 shows yet another exemplary multi-layer integrated circuit;

FIGS. 4 to 6 show schematic flow diagrams representing exemplary methods of fabricating an integrated circuit;

FIGS. 7A to 7H show an exemplary method of fabricating an integrated circuit;

FIGS. 8A to 8D show exemplary aspects of another method of fabricating an integrated circuit;

FIGS. 9A to 9B show further exemplary aspects of a method of fabricating an integrated circuit;

FIGS. 10A to 12B show schematic cross sections of exemplary integrated circuits;

FIG. 13 shows a schematic cross section of an exemplary stacked CMOS SRAM cell; and

FIG. 14 shows a schematic diagram of an exemplary multi-layer memory system.

### DETAILED DESCRIPTION OF ILLUSTRATIVE EMBODIMENTS

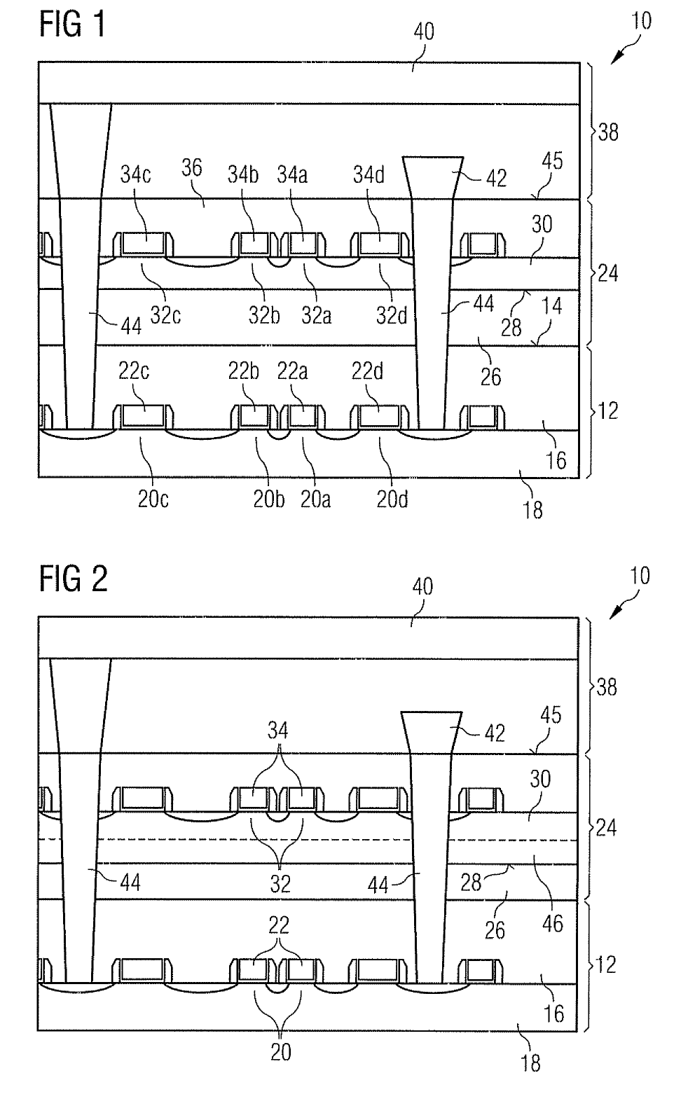

FIG. 1 shows a sectional view of an exemplary integrated circuit 10 forming an exemplary multi-layer memory device. The integrated circuit 10 comprises a first integrated circuit layer 12 having a wafer bonding surface or wafer bonding interface 14. In one aspect, the wafer bonding interface 14 may form a surface of the first integrated circuit layer 12. In one aspect, the wafer bonding interface 14 is substantially planar. In the shown example, the wafer bonding interface 14 is formed by a first inter-layer dielectric 16 comprised in the first integrated circuit layer 12, i.e., the wafer bonding interface 14 may form a surface of the first inter-layer dielectric 16. The first inter-layer dielectric 16 may comprise dielectric material such as an oxide or a nitride material, for example. In particular, silicon oxide or silicon nitride may be applied for the first inter-layer dielectric 16, for example. In one aspect, the wafer bonding interface 14 of the first inter-layer dielectric 16 may be fabricated or prepared by chemical-mechanical polishing (CMP) as exemplarily described in more detail, below.

In one aspect, the first integrated circuit layer 12 may comprise a semiconductor substrate 18 such as a silicon substrate which may be at least partly crystalline. The semiconductor substrate 18 may comprise at least part of a semiconductor wafer. In one example, the semiconductor substrate 18 may comprise bulk semiconductor material. In another example, the semiconductor substrate 18 may comprise a semiconductor layer which may be arranged on a carrier substrate, such as an at least partly insulating material or a dielectric substrate. In particular, an SOI-layer (silicon on insulator) may be applied for the semiconductor substrate 18, in one particular example.

In one aspect, the first integrated circuit layer 12 and, particularly, the semiconductor substrate 18 may comprise IC grade or transistor grade semiconductor material, such as high quality silicon, for example, i.e., the crystalline quality of the semiconductor material may be prepared or suitable for accommodating a channel region, i.e., the body of a semiconductor field effect transistor, such as a MOS-transistor, for example. In particular, the semiconductor substrate 18 may comprise at least one first transistor channel region 20a.

In the example of FIG. 1 the first integrated circuit layer 12, particularly the semiconductor substrate 18 comprises a plurality of transistor channel regions 20a, 20b, 20c, etc., each forming the body of a field effect transistor. Each transistor channel region is controlled by a gate structure of a field effect transistor. Some of the transistors may be formed as flash memory cells, where the gate structure may comprise a floating gate or a charge trapping layer as exemplarily shown in more detail below. In accordance with the example shown in FIG. 1, some of the transistors may be arranged and/or connected in series to form a cell string, where the gate structure of each transistor of the cell string is electrically connected to a word line 22a, 22b. In one example, the cell string may form at least part of a NAND memory. In this example, the source and/or drain contacts of other transistors may be electrically connected to source and/or gate contacts of the cell string and their gate structures may be electrically connected to a string select line 22c or a ground select line 22d, for example. The word lines 22a, 22b and the select lines 22c, 22d comprised in the first integrated circuit layer 12 may be at least partly embedded in or covered by the first inter-layer dielectric 16.

As shown in the example of FIG. 1, the integrated circuit 10 may comprise a second integrated circuit layer 24 arranged at the wafer bonding interface 14 of the first integrated circuit layer 12. Accordingly the wafer bonding interface 14 may form a surface of the second integrated circuit layer 24 and it may form an interface in the integrated circuit separating and connecting the first integrated circuit layer 12 and the second integrated circuit layer 24. In the shown example, the second integrated circuit layer 24 comprises a dielectric bonding layer 26 that is directly arranged at the wafer bonding interface 14 and bonded thereto via wafer bonding. The dielectric bonding layer 26 may comprise dielectric material, such as silicon oxide, for example. The dielectric bonding layer 26 comprises an operation layer support surface or operation layer support interface 28 that may be substantially opposite to the wafer bonding interface 14. An operation layer 30 comprised in the second integrated circuit layer 24 is arranged at the operation layer support surface 28, for example, and comprises crystalline semiconductor material.

In one aspect, the second integrated circuit layer 24, particularly the operation layer 30 may comprise IC grade or transistor grade semiconductor material, such as high quality silicon, for example, i.e., the crystalline quality of the semiconductor material may be prepared or suitable for accommodating a channel region, i.e., the body of a semiconductor field effect transistor, such as a MOS-transistor, for example. In particular, the operation layer 30 may comprise at least one second transistor channel region 32a that forms the body of a field effect transistor, for example. In one aspect, the operation layer may comprise a single crystalline semiconductor wafer material that may be substantially free of grain boundaries on a length of at least about 1 μm, or at least about 5 μm, or at least about 10 μm or even more than about 20 μm or about 100 μm, for example. In one example, the thickness of the operation layer may be between about 10 nm and about 300 nm, particularly at about 100 nm. Nevertheless, the thickness of the operation layer 30 is not limited to this thickness and it may even be smaller than 10 nm or greater than 300 nm in some examples.

Analogous to the first integrated circuit layer 12, the second integrated circuit layer 24, particularly the operation layer 30 may comprise a plurality of transistor channel regions 32a, 32b, 32c, etc., each forming the body of a field effect transistor. Each transistor channel region is controlled by a gate structure of a field effect transistor. Some of the transistors may be formed as flash memory cells, analogous to the transistors formed in the first integrated circuit layer 12. Moreover, some of the transistors may be arranged and/or connected in series to form a cell string of a NAND memory structure, for example, where the gate structure of each transistor of the cell string is electrically connected to a word line 34a, 34b, analogous to the first integrated circuit layer. In this example, the source and/or drain contacts of other transistors may be electrically connected to source and/or gate contacts of the cell string and their gate structures may be electrically connected to a string select line 34c or a ground select line 34d, for example. The word lines 34a, 34b and the select lines 34c, 34d comprised in the second integrated circuit layer 24 may be at least partly embedded in a second inter-layer dielectric 36.

In the example shown in FIG. 1 a wiring layer 38 is arranged at the second integrated circuit layer 24, where bit lines 40 and ground lines 42 may be provided. The integrated circuit 10 further comprises electrical inter-layer connections 44 to provide electrical connections between electrical contacts and components in the different circuit layers and/or to provide electrical connections to bit lines 40 and ground lines 42, for example.

In another example not shown in the figures, three or more bonded circuit layers may be provided. In this case the surface 45 of the second inter-layer dielectric 36 may be provided as a further wafer bonding surface or wafer bonding interface and a third integrated circuit layer may be wafer-bonded to this additional wafer bonding interface. The third and each further integrated circuit layer may be structured as exemplarily described for the second integrated circuit layer 24 above. Nevertheless, the integrated circuit 10 is not limited to an aligned arrangement of electronic components, such as transistors in the first and second integrated circuit layer. Instead, in another example, the arrangement of transistors in the second integrated circuit layer 24 may be independent of the arrangement of transistors in the first integrated circuit layer 12.

Moreover, the integrated circuit 10 is not limited to the same type of transistors or the same type of circuitry or circuitry architecture in different integrated circuit layers. Accordingly, in one example non-volatile memory cells, such as flash memory cells, for example, in the one layer may be combined with control circuitry in the other layer, for example. In another example, p-type transistors in one layer may be combined with n-type transistors in the other layer. Furthermore, different type of memories or memory architectures may be combined within the same layer or in different layers. Accordingly, NAND or NOR memory structures may be combined with cross-point-arrays, for example. In another example, a NOR-flash memory structure may be combined with an NROM cell array. Combinations of different active components are of particular interest for system-in-package concepts, for example. Accordingly, in one example a DRAM array or a pseudo-SRAM in one layer may be combined with a non-volatile memory in the other layer. A plurality of electrical inter-layer connections may be provided to allow fast and efficient transmission of electrical signals between electronic components of different levels.

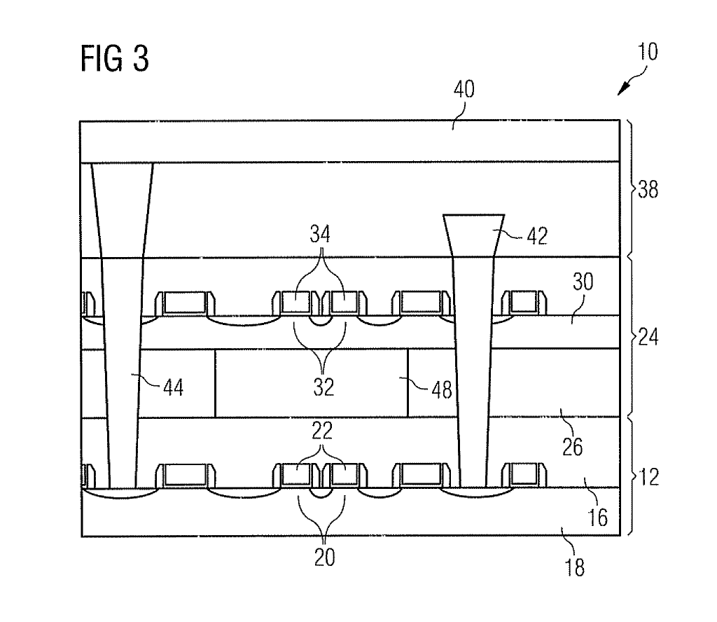

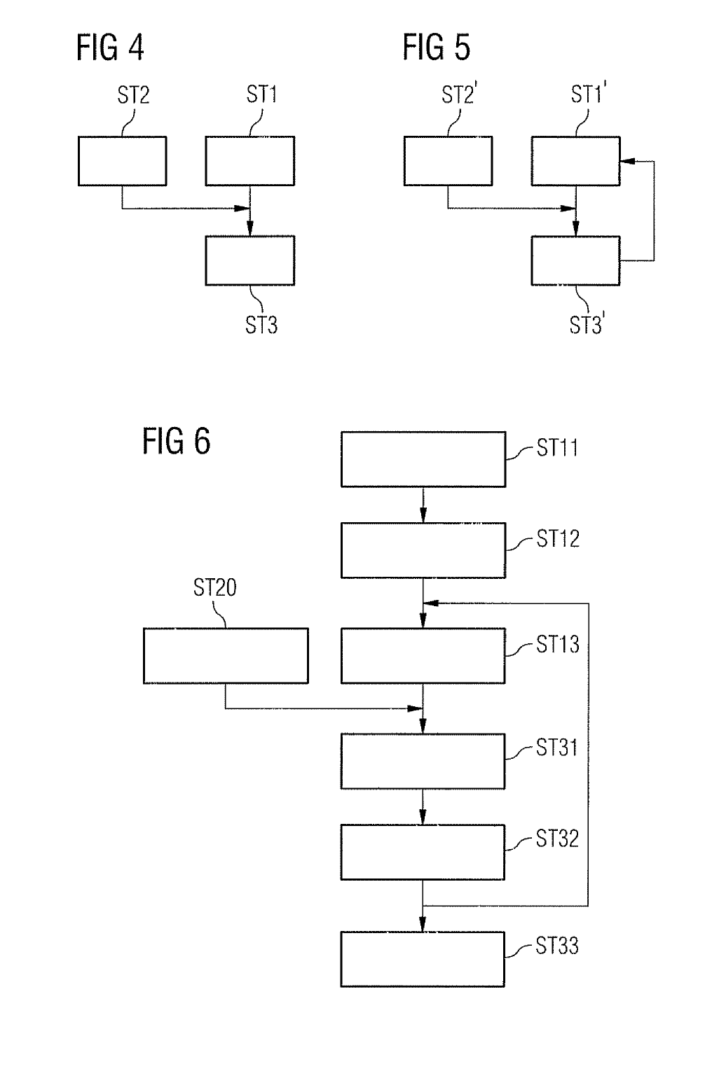

FIG. 2 and FIG. 3 show further exemplary integrated circuits 10 similar to the integrated circuit 10 described in connection with FIG. 1 above. Accordingly, analogous components are referenced with the same numerals and for detailed description it is referred to the respective description of FIG. 1 above.

In the example of FIG. 2, the operation layer 30 is at least partly doped to form a buried well, such as the buried n-well 46 shown in FIG. 2, for example. The formation of at least one buried well may allow a more efficient control of programming flash memory cells, for example, as described in more detail, below. In the example of FIG. 3, an additional electrically conductive body plate 48 may be arranged between the active components of the first and second layer. This additional body plate may be electrically connected to a tunable electrical potential and, thereby, may allow an improved control of an erase process for memory cells in the second layer, for example. The body plate 48 may comprise electrically conductive material, such as poly-Si, or other semiconductor, WSi, CoSi or other suicides, Ti or W or other suitable refractory metal, for example.

Accordingly, in one example, an integrated circuit 10 may comprise

a first integrated circuit layer 12 comprising at least one first transistor channel region 20a, i.e., one first semiconductor transistor body, and having a wafer bonding interface 14; and

at least one second integrated circuit layer 24 comprising at least one second transistor channel region 32a, i.e., one second semiconductor transistor body, and being arranged at the wafer bonding interface 14 of the first integrated circuit layer 12. In particular, the second integrated circuit layer is wafer-bonded to the first integrated circuit layer via the wafer bonding interface. In one aspect, the second integrated circuit layer may be substantially parallel to the first integrated circuit layer.

In an exemplary integrated circuit, the first integrated circuit layer 12 may comprise a first inter-layer dielectric 16 forming at least part of the wafer bonding interface 14.

In another exemplary integrated circuit 10, the second integrated circuit layer 24 may comprise:

a dielectric bonding layer 26 arranged at the wafer bonding interface 14 and having an operation layer support surface 28; and

an operation layer 30 arranged at the operation layer support surface and comprising the at least one second transistor channel region 32a.

In one exemplary integrated circuit, at least one of the first and second integrated circuit layers may comprise one or more non-volatile memory cells. In particular, at least one of the first and second integrated circuit layers may comprise one or more flash memory cells. For example, at least one of the first and second integrated circuit layers may comprise one or more NAND flash memory circuits. In another example, at least one of the first and second integrated circuit layers comprises a DRAM memory circuit. In yet another example, at least one of the first and second integrated circuit layer may comprise a capacitor.

An exemplary integrated circuit may comprise a plurality of interlayer connections electrically connecting a first integrated circuit comprised in the first integrated circuit layer and a second integrated circuit comprised in the second integrated circuit layer.

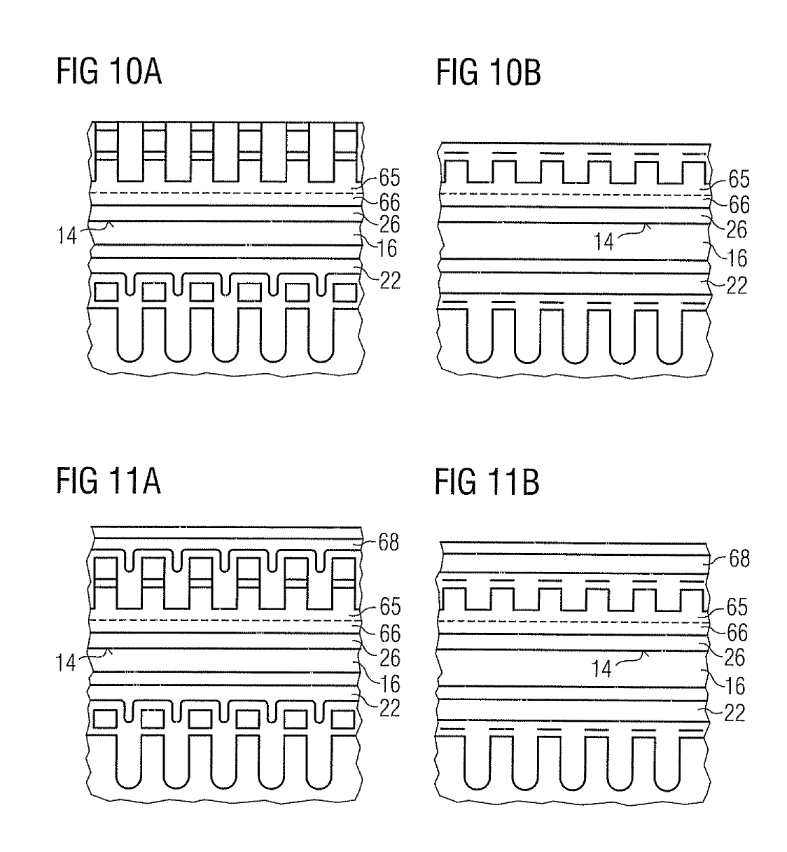

In an exemplary integrated circuit, the first and second transistor channel regions are substantially aligned to each other with respect to directions parallel to the wafer bonding interface, as exemplarily shown in FIG. 1 and FIG. 2, above, and in FIG. 10 to FIG. 12, below.

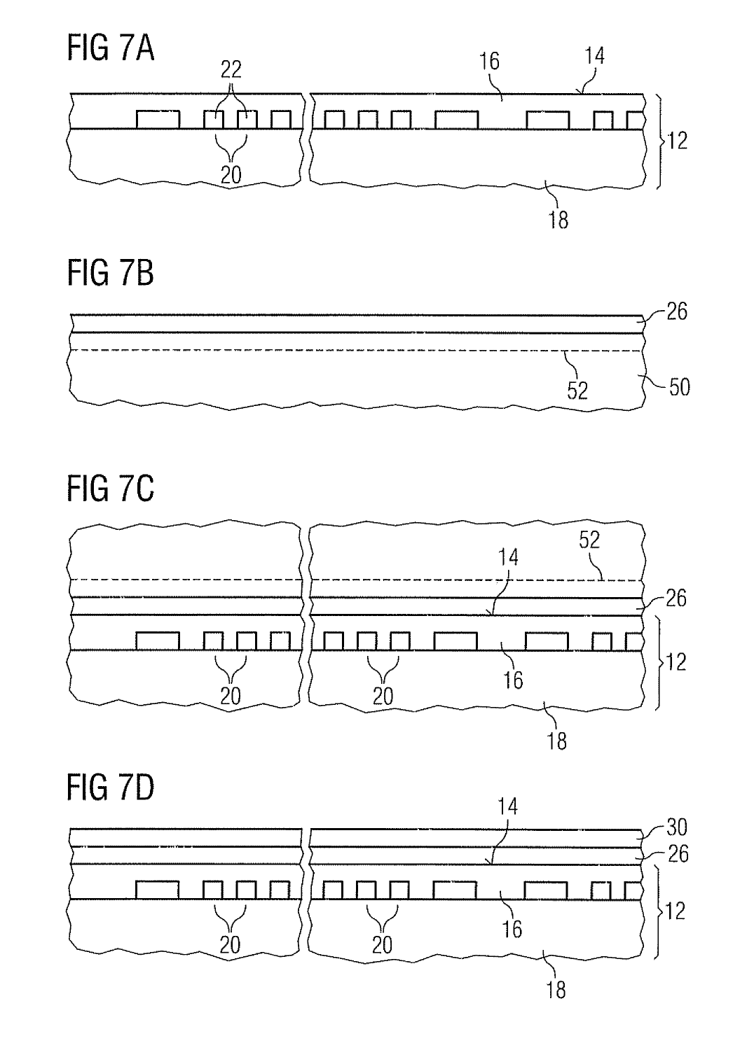

In one aspect, a method of fabricating an integrated circuit may comprise providing an integrated circuit layer with a wafer bonding interface, which may be implemented as step ST1 exemplarily shown in FIG. 4. The method may further comprise preparing a crystalline semiconductor layer, which may be exemplarily implemented as step ST2 (FIG. 4). Furthermore, the method may comprise directly or indirectly bonding the prepared crystalline semiconductor layer to the wafer bonding interface by wafer bonding, for example, which may be implemented as step ST3 shown in FIG. 4, for example.

According to another exemplary implementation shown in FIG. 5, a step ST1′ of providing an integrated circuit layer with a wafer bonding interface, a step ST2′ of preparing a crystalline semiconductor layer, and a step ST3′ of bonding the prepared crystalline semiconductor layer to the wafer bonding interface may be at least partly repeated to achieve a multi-layer integrated circuit.

FIG. 6 demonstrates yet another exemplary implementation of a method of fabricating an integrated circuit. According to this example, the method may comprise a step ST11 of supplying a first IC grade wafer. In a further exemplary step ST12 a first CMOS process may be applied to the IC grade wafer supplied in step ST11. In one example, step ST12 may comprise fabricating a first plane of NAND strings. Furthermore, in an exemplary step ST13 a wafer bonding interface may be provided by depositing an inter-layer dielectric and planarizing the inter-layer dielectric to provide the wafer bonding interface as a substantially planar surface, for example. Moreover, the method may further comprise a step ST20 of supplying a further IC grade wafer, where the further IC grade wafer may at least partly comprise the crystalline semiconductor layer. In yet another exemplary step ST31, the further IC grade wafer may be wafer bonded to the wafer bonding interface. Step ST31 may further comprise cleaving the further IC grade wafer to provide a thin crystalline semiconductor layer being directly or indirectly bonded to the wafer bonding interface. In this connection, “directly” means that the crystalline semiconductor layer may be arranged directly at or adjacent to the wafer bonding interface, while “indirectly” means that an additional bonding layer, such as a dielectric layer, for example, may be arranged between the wafer bonding interface and the crystalline semiconductor material. In a further exemplary step ST32 a further CMOS process may be applied to the crystalline semiconductor layer. In particular, a further plane of NAND strings may be fabricated with a CMOS process in step ST32, for example. In one aspect, steps ST13, ST20, ST31, and ST32 may be repeated once or several times to achieve a multi-layer integrated circuit. In yet another exemplary step ST33, contacts and/or wiring may be fabricated in one or more metal layers, as exemplarily demonstrated in FIG. 6.

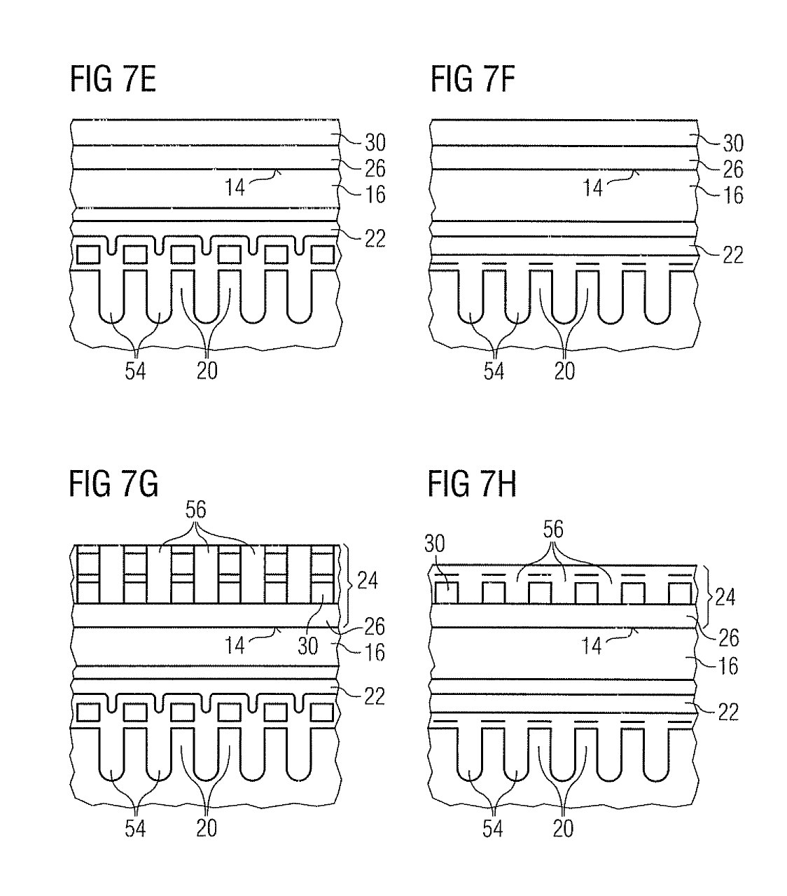

In one aspect, a method of fabricating an integrated circuit may comprise providing a first integrated circuit layer 12 with a wafer bonding interface 14 as exemplarily shown in FIG. 7A. The first integrated circuit layer 12 may be provided on a wafer level, i.e., the integrated circuit layer 12 may comprise semiconductor circuitry comprising transistor channel region 20, for example, fabricated on a first IC grade wafer, such as a Si-wafer or an SOI-wafer, for example. In particular, a first plane of NAND strings or non-volatile memory cells may be fabricated on the first wafer, for example.

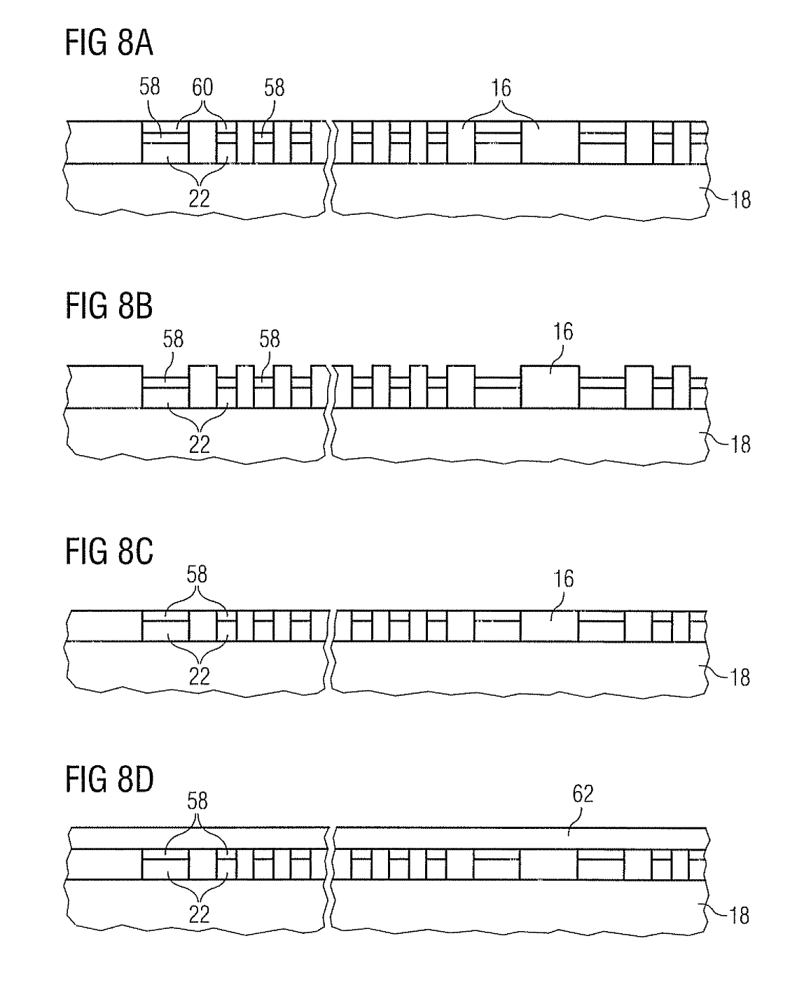

As shown in FIG. 7A, the electronic circuitry is covered or at least partly embedded by the inter-layer dielectric 16 (ILD). Accordingly, providing the first integrated circuit layer 12 may comprise covering a processed semiconductor substrate with the inter-layer dielectric 16, such as SiO₂, for example. Furthermore, providing the first integrated circuit layer 12 may comprise planarizing a surface of the inter-layer dielectric 16 to provide the wafer bonding interface 14 as a substantially planar surface. Planarizing the inter-layer dielectric 16 may comprise chemical-mechanical polishing, for example. In one aspect, dishing of the wafer bonding interface after planarizing may be less than 5 nm, or even less than 1 nm per 10 μm lateral extension. Further exemplary steps of planarizing are explained in more detail in connection with FIG. 8, below.

A method of fabricating an integrated circuit may further comprise preparing a crystalline semiconductor layer. In one aspect, preparing the crystalline semiconductor layer may comprise providing the crystalline semiconductor layer with a substantially planar surface.

In another aspect exemplarily shown in FIG. 7B, preparing the crystalline semiconductor layer 50 comprises arranging a dielectric bonding layer 26 at the crystalline semiconductor layer 50. In particular, a second semiconductor wafer may be applied as starting material for preparing the crystalline semiconductor layer 50. Even further, a method of fabricating an integrated circuit may comprise bonding the prepared crystalline semiconductor layer to the wafer bonding interface. According to the example shown in FIG. 7B, the so-prepared crystalline semiconductor layer 50 may be bonded to the first integrated circuit layer 12 by bonding the dielectric bonding layer 26 to the wafer bonding interface 14, as shown in FIG. 7C, for example, i.e., bonding the prepared crystalline semiconductor layer to the wafer bonding interface may comprise bonding the dielectric bonding layer to the wafer bonding interface of the first integrated circuit layer.

Preparing the crystalline semiconductor layer may further comprise implanting an embrittlement zone 52 in the crystalline semiconductor layer 50, e.g., by H-implantation. The method may further comprise detaching or cleaving part of the crystalline semiconductor layer 50 at the embrittlement zone 52 after bonding the prepared crystalline semiconductor layer 50 to the wafer bonding interface 14. In one example cleaving may occur in accordance with a method called “smart cut”. The remaining part of the crystalline semiconductor layer 50 may form at least part of the operation layer 30 described above, as exemplarily shown in FIG. 7D. In one aspect, the operation layer 30 may comprise single crystalline semiconductor material that may be substantially mono-crystalline on a length of at least about 1 μm, or at least about 5 μm, at least about 10 μm or even more than about 20 μm or about 100 μm, for example, in at least one direction parallel to the wafer bonding interface 14 or even in each direction within a plane parallel to the wafer bonding interface 14.

In another example, the method may further comprise applying a CMOS process to the bonded crystalline semiconductor layer or the operation layer 30. Exemplary CMOS process are schematically shown in FIGS. 7E to 7H, where cross sections of the circuit of FIGS. 7A to 7D are shown by 90° rotated, i.e., the sectional plane is perpendicular to the longitudinal extension of the cell strings. Therefore, the depicted transistor channel regions 20 belong to different cell strings and the cell strings are separated from each other by shallow trench isolations 54 (STI). FIG. 7E and FIG. 7F show exemplary sectional views of an integrated circuit at a process step analogous to FIG. 7D, where in the example of FIG. 7E a floating gate NAND has been processed in the first integrated circuit layer, while FIG. 7F shows an example with a charge trapping NAND.

In the examples of FIG. 7G and FIG. 7H a respective CMOS process analogous or similar or even substantially identical to that in the first integrated circuit layer 12 has also been applied to the respective operation layer 30, thereby forming an analogous circuitry in the first and second integrated circuit layer, for example. In particular, in these shown examples, applying the CMOS process comprises structuring the crystalline semiconductor layer, i.e., the operation layer 30, to form separated active areas electrically isolated from each other by dielectric filling material 56. In particular, each active area comprises at least one transistor body. Accordingly, in these examples, in the second integrated circuit layers 24 the active areas substantially form strips and the dielectric filling material 56 in the second layer takes the position of the STI in the first layer. Accordingly, in one exemplary integrated circuit the second integrated circuit layer 24, particularly the operation layer 30, may comprise a structured crystalline semiconductor layer 50 having a plurality of isolation trenches, exemplarily filled with the dielectric filling material 56, formed therein.

Additional examples of CMOS processes to be applied to the operation layer 30 are described with reference to FIGS. 10 to 12, below.

FIGS. 8A to 8D show another example of planarizing the interlayer dielectric. According to this example, the first integrated circuit layer 12 may be provided with a hardmask layer 58 and an etch stop layer 60 arranged on the word line 22 and/or the select lines, for example. In one particular example, the etch stop layer 60 may comprise Al₂O₃ and/or carbon. The hardmask layer 58 may comprise nitride, for example, while the inter-layer dielectric material may substantially comprise or consist of SiO₂, for example.

According to the shown example, planarizing the inter-layer dielectric comprises chemical-mechanical polishing the first inter-layer dielectric 16 down to the etch stop layer 60 provided in the integrated circuit layer particularly, in the inter-layer dielectric, as shown in FIG. 8A. Furthermore, FIG. 8B shows a step of removing the etch stop layer 60. Subsequently, the method may comprise chemical-mechanical polishing of the inter-layer dielectric to remove it down to the hardmask layer 58 provided in the integrated circuit layer particularly, in the first inter-layer dielectric 16, as shown in FIG. 8C. According to a further exemplary step shown in FIG. 8D, the method may comprise depositing a uniform oxide layer 62, such as TEOS, for example.

In one example not shown in the figures, the method may further comprise an additional oxide CMP step without a CMP stop material. In some case this may improve the smoothness even further. In yet another example, the method may comprise applying a surface treatment to prepare for wafer bonding.

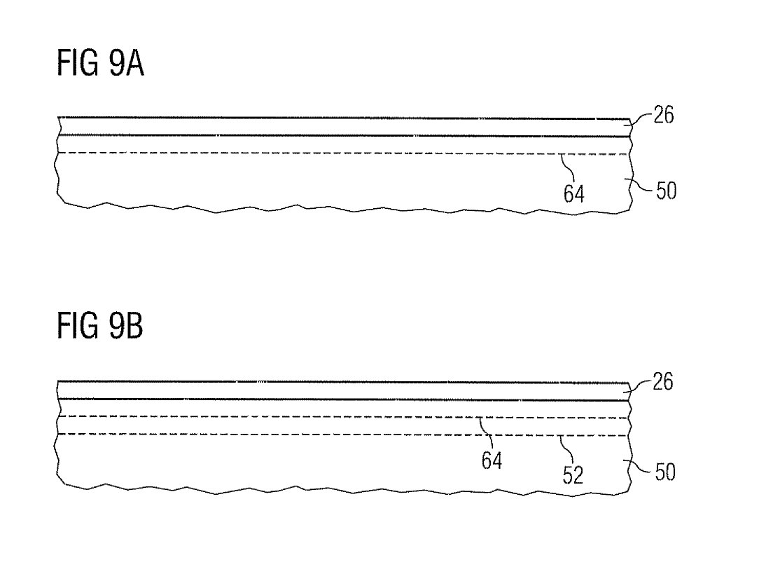

FIG. 9 shows another example of preparing the crystalline semiconductor layer 50. According to this example, the method comprises implanting at least one species of dopant 64 into the crystalline semiconductor layer 50 and annealing the crystalline semiconductor layer 50 to form at least a first buried doped well (FIG. 9A). Phosphorus (P) may be applied for n-type doping of silicon, for example, thereby forming an n-well. Furthermore, as shown in FIG. 9B, an exemplary H-implantation may result in the formation of the embrittlement zone 52, as already mentioned above, exemplarily. Implantation of H may be performed to a greater depth into the crystalline semiconductor layer 50 than implantation of the dopant 64 (FIG. 9B).

FIGS. 10A to 12B show further examples of fabricating integrated circuits, and particularly of applying a CMOS process to the crystalline semiconductor layer, i.e., the operation layer 30. According to these examples, the crystalline semiconductor layer, i.e., the operation layer 30, is not completely structured into separate semiconductor strips. Instead, it is etched only to a certain depth such that a common extended doped well remains at the dielectric bonding layer 26. In particular, in one example an extended p-well 65 may be provided above an n-well 66 as exemplarily shown in FIGS. 10A to 12B. The exemplary n-well 66 may be achieved by P-implantation, as described in connection with FIG. 9 above.

Accordingly, in one exemplary integrated circuit, the second integrated circuit layer may comprise a p-doped well and an n-doped well both extending substantially parallel to the wafer bonding interface and forming together a p-n-junction, the direction substantially perpendicular to the wafer bonding interface.

In another exemplary integrated circuit, the n-doped well and the p-doped well are electrically connected to voltage application contacts for applying an electron acceleration voltage. This may be of particular interest for flash memories, where the programming efficiency may be improved in one example.

According to the examples of FIG. 11A and FIG. 11B applying a CMOS process may further comprise forming second layer word lines 68. In the particular example of FIG. 11A, in case of a floating gate device, forming second layer word lines may comprise one or more of the steps removing a hardmask, depositing a coupling dielectric, depositing a control gate as word line 68 and patterning word line stacks. In the example of FIG. 11B, in case of a charge trapping device, forming second layer word lines may comprise one or more of the steps removing a hardmask, depositing a control gate as a word line, and patterning word line stacks. Moreover, applying a CMOS process may further comprise one or more of the steps of isolation filling, planarization, and contacting bit lines and metal wiring.

In further examples, providing a wafer bonding interface, preparing a crystalline semiconductor layer, and bonding the prepared crystalline semiconductor layer to the wafer bonding interface may be repeated in an analogous manner for providing one or more additional integrated circuit layers.

In FIGS. 12A and 12B an exemplary programming technique for NAND cells on a wafer level is shown. In accordance with this technique, an exemplary method of fabricating an integrated circuit as described herein may comprise providing electrical connections 70 both to the buried n-well 66 and the p-well 65. An exemplary method of programming a memory cell may comprise applying electrical voltage to the electrical connections 70 to inject substrate hot electrons into the storage layer in conjunction with a modified inhibit scheme to enhance program efficiency. In particular, according to this method electrons may be accelerated in the biased n-p-junction formed by the combination of n-well and p-well. The electrons gain a higher potential across this n-p-junction resulting in an enhanced tunneling probability towards the storage layer. This may be applied both for floating gate cells (FIG. 12A) and for charge trapping cells (FIG. 12B).

Accordingly, in one exemplary aspect, programming may employ substrate hot electron injection in memory cells, such as flash memory cells, for stacked planes. In particular, an n-p-junction configuration may take advantage of implanting the second substrate or wafer, i.e., the crystalline semiconductor layer 50 prior to the wafer-bonding procedure. A substrate contact formed by one of the electrical connections 70 may connect the buried n-well 66 of the bonded plane. Thus, a potential that is negative with respect to the p-well, may be applied to generate the hot carriers.

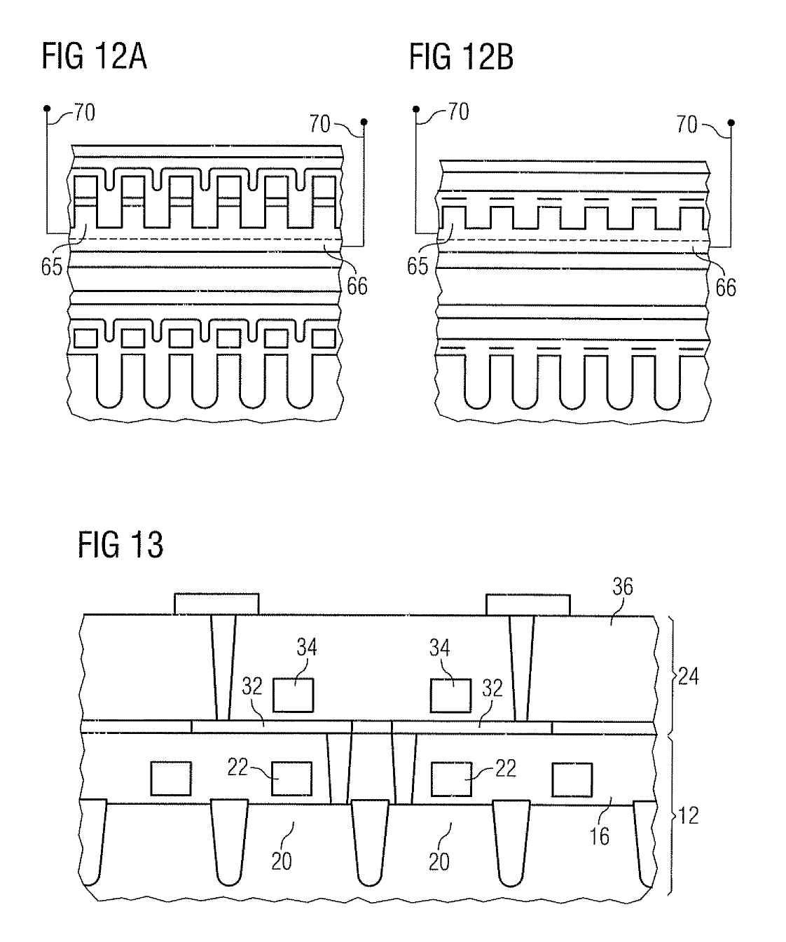

In one aspect, as already explained above, the integrated circuit 10 is not limited to NAND memory device. It is not even limited to non-volatile memory. Instead, according to one particular aspect, the described stacked integrated circuit may be provided as a SRAM device, for example. FIG. 13 shows an exemplary stacked 6-transistor SRAM cell. In particular, for rather large memory cells, such as SRAMs, stacking as described herein may be applied. In the exemplary double-layer integrated circuit of FIG. 13 analogous components as in the above described examples are referenced with the same numeral. Accordingly, the detailed description given above in view of these components applies analogously.

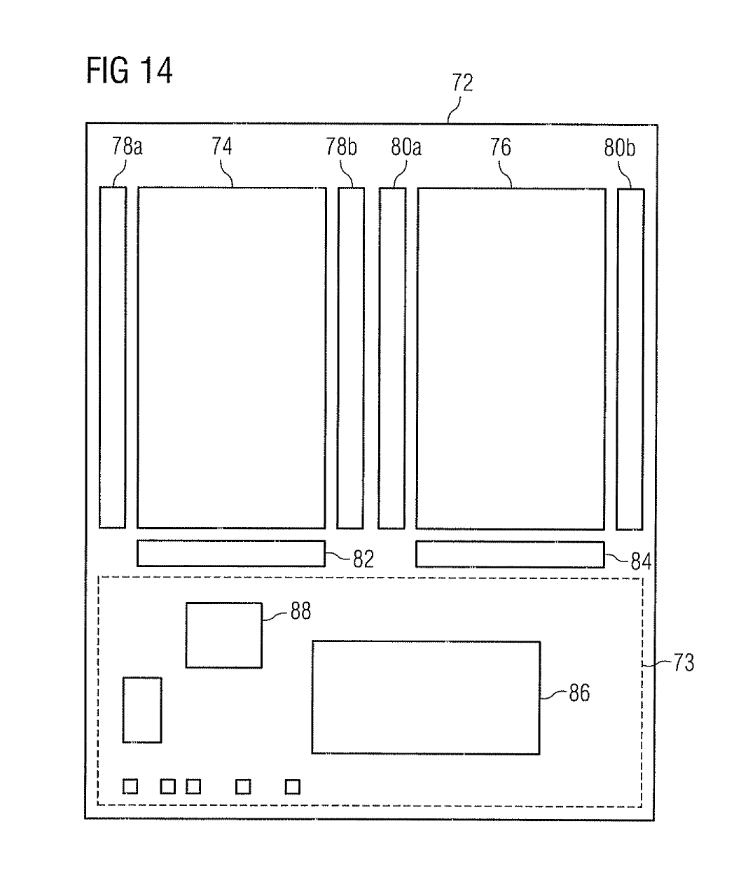

According to yet another aspect an exemplarily multi-media system may comprise at least one multi-layer storage region, such as the integrated multi-layer memory system 72 exemplarily shown in FIG. 14. In one example, the multi-layer storage region may have a plurality of storage sites, such as the memory cells exemplarily described above, arranged in two or more at least partly crystalline semiconductor storage layers, such as the above described integrated circuit layers, for example. These storage layers are separated by a wafer bonding interface, wherein at least some of the storage sites of different storage layers are electrically connected to each other via electrical interconnections penetrating the wafer bonding interface.

In one aspect, this multi-media system may exhibit high data transfer rates, i.e., a high read and write speed in the storage region. In particular, the resulting high storage density together with a possibly large number of rather short interconnection lines may allow a large data throughput needed for demanding tasks performed with a multi-media system.

In an exemplary multi-media system, the at least one multi-layer storage region comprises:

a first integrated circuit layer comprising at least one first transistor channel region and having a wafer bonding interface; and

at least one second integrated circuit layer comprising at least one second transistor channel region and being arranged at the wafer bonding interface of the first integrated circuit layer.

In particular examples, the described multi-media system may be implemented as a computer (mobile computer, laptop), mobile phone (cellular phone), smart phone, PDA, USB-drive, Camera (digital camera), Camcorder, MP3-player, portable electronic product, such as a portable audio and video player, a cellular phone, a USB memory or a solid state disks for PC, for example. Any kind of consumer electronic device, such as a TV, a radio, or any house hold electronic device, for example, or any kind of storage device, such as a chip card or memory card, for example, may be implemented as described herein.

According to the example shown in FIG. 14, an integrated multi-layer memory system 72 may be implemented as an integrated hybrid system. In particular, both storage sites and control circuitry or logic circuitry 73 may be implemented integrally, wherein in one example a plurality or even all or the integrally implemented circuits are provided as stacked or multi-layer integrated circuit as described herein. The exemplary integrated multi-layer memory system 72 of FIG. 14 comprises several storage sectors 74, 76, which may comprise non-volatile memory arrays such as multi-layer NAND flash memory arrays, for example. Address decoders 78a, 78b, 80a, 80b and page buffers 82, 84 may be provided for each of the memory arrays. In one example, a separate address decoder and/or a separate page decoder may be provided for each circuit layer of the memory arrays. The logic circuitry 73 may comprise a CPU 86, a cache 88, such as a multi-layer SRAM, and other components, such as charge pumps, I/O devices and contact pads, for example.

In one aspect a manufacturing method may relate to multi plane NAND memories and, in particular, to use laminates of the highest quality single crystal Si to obtain additional transistor bodies stacked above the bottom transistor plane.

In one aspect, a concept of a multi plane NAND memory may utilize multiple Si single crystal, wafer based, substrates that are stacked to obtain integrated circuits. In one aspect, the circuits feature transistors to be stacked vertically, but are manufactured in only one semiconductor wafer fabrication process, i.e., substantially the same or an analogous process flow may be applied in processing electronic components, such as memory cell, or cell strings, for example, in the first and second integrated circuit layer. In particular, an exemplary method may be applied for manufacturing multi-plane NAND memories with transistors based on high quality single crystal semiconductor material, the transistors are stacked in different planes of a single circuitry.

Accordingly, in one particular aspect, charge trapping NAND memories may be provided as multi layer, stacked type NAND string arrays that feature monolithic integration. In the described technology, the Si active layers may be stacked with minimum processes and may be interconnected simultaneously with the bottom cell arrays and the peripheral circuits, for example. Also, it may improve the electrical characteristics by reducing the capacitive and resistive loading without reducing the cell current.

In one aspect, in a stacked NAND array a first string level may be directly manufactured on a silicon substrate and one or more additional levels may be manufactured by wafer bonding. In one particular example, each of the additional string levels may also be mounted on or above an individual plate, such as body plates, for example. This may allow the second, third, etc. string levels to be programmed and erased in the same way as the first level independent from the other levels.

In an exemplary doubly stacked NAND Flash, cell strings of the upper layers may be stacked over the cell strings of the bottom layer ones already formed on the bulk Si Substrate, for example. The cell strings may have, for example, TANOS (TaN—AL₂O₃-Nitride-Oxide-Silicon) or SONOS (silicon-oxide-nitride-Oxide-Silicon) structures. In order to achieve the same electrical characteristics of the cell strings in both layers, high-quality SOI-like single crystal Si layers may be formed on the ILD layers. The bit line contacts and the common source lines may, for example, be patterned simultaneously on both layers of the cell string by etching layers vertically through the upper level Si layers to the bottom active layer. The bit line holes are filled sequentially with the N-doped poly-Si and W, for example. Therefore, both of the cell strings are connected through a single contact hole to the same bit line. The x-decoders of the upper and lower cell arrays may be laid out separately at the other ends of the arrays. In one example, only four additional photo layers are used to double the density of NAND cells by stacking cell arrays on the ILD.

The term charge trapping storage should not be understood as nitride storage solely, but should be seen as any storage or charge retention principle that can retain charge carriers even in non-uniform material. That could be a material combination of a single or multi-layer dielectric with embedded metal clusters or interface traps between particular layers. It could be any kind of dielectric that has retention sites for charge carriers. It could be nanodots or nanocrystals, too.

A number of examples and implementations have been described. Other examples and implementations may, in particular, comprise one or more of the above features. Nevertheless, it will be understood that various modifications may be made.

For example, neither the first nor any other of the applied inter-layer dielectrics are limited to the explicitly described or mostly cited materials. Instead or additionally any other dielectric or isolation material or combinations thereof may be applied for the inter-layer dielectric, for example. Moreover, also the described semiconductor layers are not limited to the explicitly mentioned material. Instead, the described concept of stacking integrated circuits may be applied with any other semiconductor material.

Moreover, the integrated circuit layers and the transistor bodies are not limited to be applied or implemented in the explicitly shown and described NAND or SRAM circuits. Instead, any other volatile or non-volatile memory circuits as well as other processing or control circuits or any other electronic circuit may be implemented in the way described herein. Accordingly, also these variations fall within the following claims.

What is claimed is:

1. An integrated circuit comprising:
a first integrated circuit layer comprising at least one first transistor channel region and having a wafer bonding interface; and
at least one second integrated circuit layer comprising at least one second transistor channel region and being arranged at the wafer bonding interface of the first integrated circuit layer.

2. The integrated circuit of claim 1, wherein the first integrated circuit layer comprises a first inter-layer dielectric forming at least part of the wafer bonding interface.

3. The integrated circuit of claim 1, wherein the second integrated circuit layer comprises:
a dielectric bonding layer arranged at the wafer bonding interface and having an operation layer support surface; and
an operation layer arranged at the operation layer support surface and comprising the at least one second transistor channel region.

4. The integrated circuit of claim 1, wherein the first and second transistor channel regions are substantially aligned to each other with respect to directions parallel to the wafer bonding interface.

5. The integrated circuit of claim 1, wherein the second integrated circuit layer comprises a p-doped well and an n-doped well, both extending substantially parallel to the wafer bonding interface and forming together a p-n-junction the direction substantially perpendicular to the wafer bonding interface.

6. The integrated circuit of claim 5, wherein the n-doped well and the p-doped well are electrically connected to voltage application contacts.

7. The integrated circuit of claim 1, wherein the second integrated circuit layer comprises a crystalline semiconductor layer having a plurality of isolation trenches formed therein.

8. The integrated circuit of claim 1, wherein at least one of the first and second integrated circuit layers comprise one or more non-volatile memory cells.

9. The integrated circuit of claim 8, wherein at least one of the first and second integrated circuit layers comprises one or more NAND flash memory circuits.

10. The integrated circuit of claim 1, comprising at least one SRAM cell that comprises a plurality of transistors, one of which comprises the first transistor channel region and one of which comprises the second transistor channel region.

11. A multi-layer NAND flash memory comprising:
a first integrated circuit layer comprising at least one first NAND flash cell string and having a wafer bonding interface; and
at least one second integrated circuit layer comprising at least one second NAND flash cell string and being wafer bonded to the wafer bonding interface of the first integrated circuit layer.

12. The multi-layer NAND flash memory of claim 11, wherein the first and the second NAND flash cell strings are aligned with respect to each other in directions parallel to the wafer bonding interface.

13. The multi-layer NAND flash memory of claim 11, further comprising a plurality of interlayer connections providing simultaneous electrical connection to the first and second NAND flash cell string.

14. A multi-media system comprising at least one multi-layer storage region having a plurality of storage sites arranged in two or more at least partly crystalline semiconductor storage layers separated by a wafer bonding interface, wherein at least some of the storage sites of different storage layers are electrically connected to each other via electrical interconnections penetrating the wafer bonding interface.

15. The multi-media system of claim 14, wherein the at least one multi-layer storage region comprises:
a first integrated circuit layer comprising at least one first transistor channel region and having a wafer bonding interface; and
at least one second integrated circuit layer comprising at least one second transistor channel region and being arranged at the wafer bonding interface of the first integrated circuit layer.

16. A method of fabricating an integrated circuit, the method comprising:
providing a first integrated circuit layer with a wafer bonding interface;
preparing a crystalline semiconductor layer; and
bonding the prepared crystalline semiconductor layer to the wafer bonding interface.

17. The method of claim 16, wherein providing the first integrated circuit layer comprises:
covering a processed semiconductor substrate with an inter-layer dielectric; and
planarizing a surface of the inter-layer dielectric to provide the wafer bonding interface as a substantially planar surface.

18. The method of claim 17, wherein planarizing the inter-layer dielectric comprises:
chemical-mechanical polishing the inter-layer dielectric down to an etch stop layer provided in the integrated circuit layer;
removing the etch stop layer;
chemical-mechanical polishing the inter-layer dielectric down to a hardmask layer provided in the integrated circuit layer; and
depositing a uniform oxide layer.

19. The method of claim 16, wherein preparing the crystalline semiconductor layer comprises providing the crystalline semiconductor layer with a substantially planar surface.

20. The method of claim 16, wherein preparing the crystalline semiconductor layer comprises arranging a dielectric bonding layer at the crystalline semiconductor layer and wherein the prepared crystalline semiconductor layer is bonded to the first integrated circuit layer by bonding the dielectric bonding layer to the wafer bonding interface.

21. The method of claim 16, wherein preparing the crystalline semiconductor layer comprises implanting an embrittlement zone in the crystalline semiconductor layer and wherein the method further comprises detaching part of the crystalline semiconductor layer at the embrittlement zone after bonding the prepared crystalline semiconductor layer to the wafer bonding interface.

22. The method of claim 16, wherein preparing the crystalline semiconductor layer comprises:
implanting at least one species of dopant into the crystalline semiconductor layer; and
annealing the crystalline semiconductor layer to form at least a first buried doped well.

23. The method of claim 16, further comprising applying a CMOS process to the bonded crystalline semiconductor layer.

24. The method of claim 23, wherein applying a CMOS process comprises structuring the crystalline semiconductor layer to form separated active areas electrically isolated from each other by dielectric filling material.

25. The method of claim 23, wherein applying a CMOS process comprises structuring the crystalline semiconductor layer to from active areas with a common extended doped well.

26. The method of claim 23, comprising substantially the same CMOS process flow for fabrication transistor structures in the first integrated circuit layer and in the bonded crystalline semiconductor layer.
